(19) United States
(12) Patent Application Publication
(10) Pub. No.: US 2016/0099366 A1
(43) Pub. Date: Apr. 7, 2016

(54) SOLAR CELL MODULE AND METHOD FOR MANUFACTURING THE SAME

(71) Applicant: KOREA INSTITUTE OF ENERGY RESEARCH, Daejeon (KR)

(72) Inventors: Young Joo Eo, Daejeon (KR); Jihye Gwak, Daejeon (KR); Ara Cho, Daejeon (KR); Se Jin Ahn, Daejeon (KR); Seoung Kyu Ahn, Daejeon (KR); Jun Sik Cho, Daejeon (KR); Joo Hyung Park, Daejeon (KR); Jin Su You, Seoul (KR); Jae Ho Yun, Daejeon (KR); Ki Hwan Kim, Daejeon (KR); Kyung Soo Kim, Daejeon (KR); Kyung Hoon Yoon, Daejeon (KR); Kee Shik Shin, Daejeon (KR)

(21) Appl. No.: 14/876,643

(22) Filed: Oct. 6, 2015

(30) Foreign Application Priority Data
Oct. 7, 2014 (KR) 10-2014-0134625

(51) Int. Cl. H01L 31/05; H01L 27/142; H02S 40/36; H01L 31/18

(52) U.S. Cl. CPC H01L 31/0508; H01L 31/0512; H01L 31/18; H01L 27/142; H02S 40/36

(57) ABSTRACT

A solar cell module, a method for manufacturing the solar cell module, a solar power system, and an interconnection ribbon are provided. The solar cell module includes a plurality of solar cells which are connected in series or in parallel through interconnection ribbons, wherein the interconnection ribbons have a zigzag shape to reduce tension generated according to bending of the solar cell module.

### CROSS-REFERENCE TO RELATED APPLICATION

This application claims foreign priority to and the benefit of Korean Patent Application No. 10-2014-0134625, filed on Oct. 7, 2014, the disclosure of which is incorporated herein by reference in its entirety.

### BACKGROUND

1. Technical Field

The present invention relates to a solar cell module and a method for manufacturing the same. More specifically, the present invention relates to a solar cell module in which interconnection ribbons for connection among a plurality of solar cells are formed in zigzag to reduce tension generated according to bending of the solar cell module, and a method for manufacturing the same.

2. Description of the Related Art

A solar cell plays a role of converting solar energy into electric energy, is made of silicon, gallium arsenide, cadmium telluride, cadmium sulfide, indium phosphide, which are semiconductor materials, or composite materials thereof, and generally, is made of mainly silicon.

The solar cell is manufactured by forming a p-n junction of a semiconductor material by a diffusion method, a photovoltaic effect in which a small amount of current flows when receiving light is used therein, most of normal solar cells are made of p-n junction diodes with a large area and, when electromotive force generated at both extremes of the p-n junction diode is connected to an external circuit, the solar cells serve as unit solar cells and battery cells.

Since the battery cell configured as described above has less electromotive force, a plurality of battery cells are connected to configure a solar cell module (photovoltaic module) having appropriate electromotive force.

In a main body of the solar cell module, a plurality of battery cells are disposed, and the battery cells are connected through interconnection ribbons coated with lead. The interconnection ribbons connected to the battery cells disposed finally up and down are connected to a bus ribbon in series or in parallel, and the bus ribbon is connected to an external terminal. In such a solar cell module, a thermal junction process of modularizing the solar cells by connecting them to the bus ribbon through the interconnection ribbons is referred to as tabbing.

In the related art, there is a problem that, when the solar cell module is bent, tension is applied to the interconnection ribbon and thus a contact portion between the interconnection ribbon and the battery cell is disconnected.

In order to solve the problem, there is a need of a solar cell module in which interconnection ribbons for connecting a plurality of solar cells are formed in zigzag to reduce tension generated according to bending of the solar cell module, and a method for manufacturing the same. The related art is disclosed in Korean Laid-Open Patent No. 10-2014-0105635.

### SUMMARY

In one aspect, some embodiments of the invention have been made to solve the problem. In another aspect, an object of at least some embodiments of the invention is to provide a solar cell module in which interconnection ribbons for connecting a plurality of solar cells are formed in zigzag to reduce tension generated according to bending of the solar cell module.

In order to achieve the object, according to some embodiments of the invention, there is provided a solar cell module including a plurality of solar cells which are connected in series or in parallel through interconnection ribbons, wherein the interconnection ribbons are formed in zigzag to reduce tension generated according to bending of the solar cell module.

In this case, a length of the interconnection ribbon may be inversely proportional to a minimum radius of curvature that is a radius in a state where the solar cell module is bent to the maximum.

In this case, a length of the first interconnection ribbon connected between the first solar cell and the second solar cell of the plurality of solar cells may be different from a length of the second interconnection ribbon connected between the second solar cell and the third solar cell of the plurality of solar cells.

In this case, the interconnection ribbon may be formed of a copper (Cu) electrode coated with alloy including lead (Pb).

In this case, the alloy including lead (Pb) may be tin-lead (Sn—Pb) alloy or tin-lead-silver (Sn—Pb—Ag) alloy.

In this case, the solar cell may include a flexible substrate.

In addition, in order to achieve the object, according to some embodiments of the invention, there is provided a method for manufacturing a solar cell module including a plurality of solar cells connected in series or in parallel through interconnection ribbons, including the steps of: tabbing interconnection ribbons which are formed in zigzag to reduce tension generated according to bending of the solar cell module, to bus bars formed in the solar cells; connecting the solar cells by interconnecting the solar cells using the interconnection ribbons attached to the bus bars; sequentially stacking tempered glass, an EVA sheet, the connected solar cell, an EVA sheet, and a back sheet, and then performing lamination; and connecting a terminal to the solar cell module.

In this case, a length of the interconnection ribbon may be inversely proportional to a minimum radius of curvature that is a radius in a state where the solar cell module is bent to the maximum.

In this case, a length of the first interconnection ribbon connected between the first solar cell and the second solar cell of the plurality of solar cells may be different from a length of the second interconnection ribbon connecting the second solar cell to the third solar cell of the plurality of solar cells.

In this case, the interconnection ribbon may be formed of a copper (Cu) electrode coated with alloy including lead (Pb).

In this case, the alloy including lead (Pb) may be tin-lead (Sn—Pb) alloy or tin-lead-silver (Sn—Pb—Ag) alloy.

In addition, in order to achieve the object, according to some embodiments of the invention, there is provided a solar power system including a solar cell module including a plurality of solar cells which are connected in series or in parallel through interconnection ribbons, wherein the interconnection ribbons are formed in zigzag to reduce tension generated according to bending of the solar cell module.

In addition, in order to achieve the object, according to some embodiments of the invention, there is provided an interconnection ribbon which connects a plurality of solar cells in series or in parallel, wherein the interconnection ribbon is formed in zigzag to reduce tension generated according to bending of a solar cell module formed by connecting a plurality of solar cell.

In this case, a length of the interconnection ribbon may be inversely proportional to a minimum radius of curvature that is a radius in a state where the solar cell module is bent to the maximum.

### BRIEF DESCRIPTION OF THE DRAWING(S)

FIG. 1 is a front view illustrating that solar cells are connected by an interconnection ribbon in the related art;

FIG. 2 is a plan view illustrating that solar cells are connected by an interconnection ribbon in the related art;

FIG. 3 is a plan view illustrating a solar cell module which is formed by interconnection ribbons in the related art;

FIG. 4 is a front view illustrating a solar cell module which is formed by interconnection ribbons in the related art;

FIG. 5 is a view illustrating a problem of a solar cell module which is formed by interconnection ribbons in the related art;

FIG. 6 is a front view that solar cells are connected by an interconnection ribbon according to some embodiments of the invention;

FIG. 7 is a front view illustrating a solar cell module according to some embodiments of the invention;

FIG. 8 is a view for explaining an effect of a solar cell module according to some embodiments of the invention; and

FIG. 9 is a flowchart illustrating a method for manufacturing a solar cell module according to some embodiments of the invention.

### DETAILED DESCRIPTION

At least some embodiments of the invention will be described in detail with reference to the accompanying drawings. Herein, the repeated description, and the known functions and configurations which may unnecessarily blur the gist of some embodiments of the invention are not described.

At least some embodiments of the invention are provided to further completely explain the invention for persons skilled in the art. Accordingly, shape, sizes, and the like of elements in the drawings may be magnified for clearer description.

In some embodiments of the invention, in a solar cell module in which at least two solar cells are connected in series or in parallel through an interconnection ribbon and a bus ribbon, there are disclosed an interconnection ribbon which is formed in zigzag to reduce tension generated according to bending of the solar cell module, the solar cell module which includes the interconnection ribbon, a method for manufacturing the same, and a solar power system.

Hereinafter, the related art corresponding to some embodiments of the invention will be described in detail with reference to the drawings.

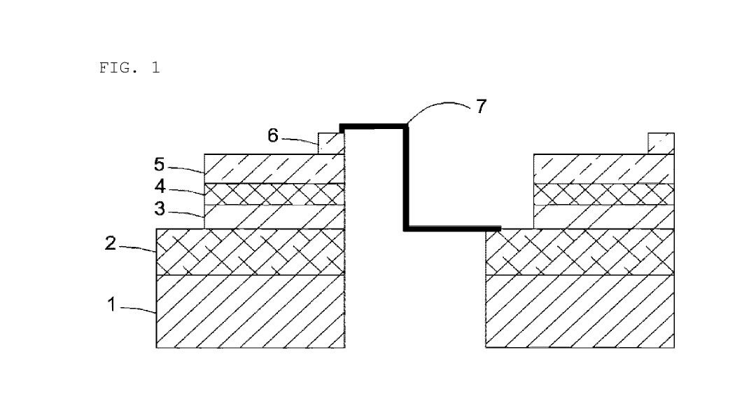

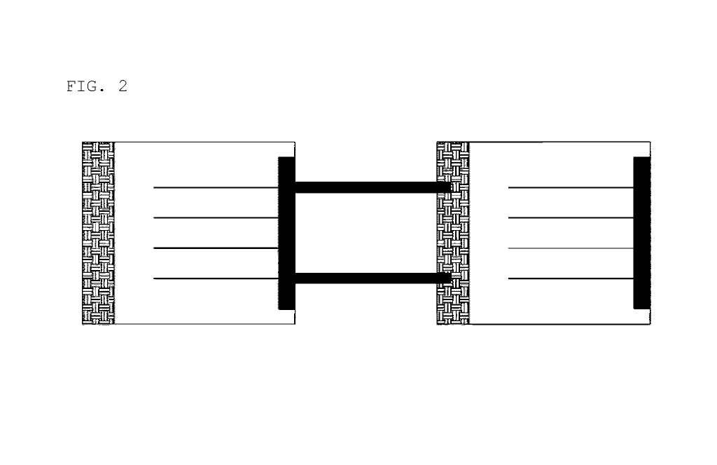

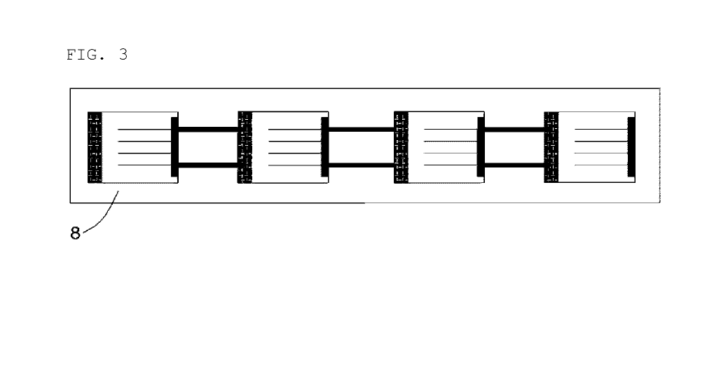

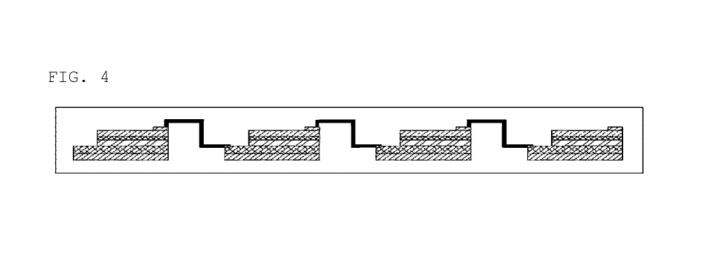

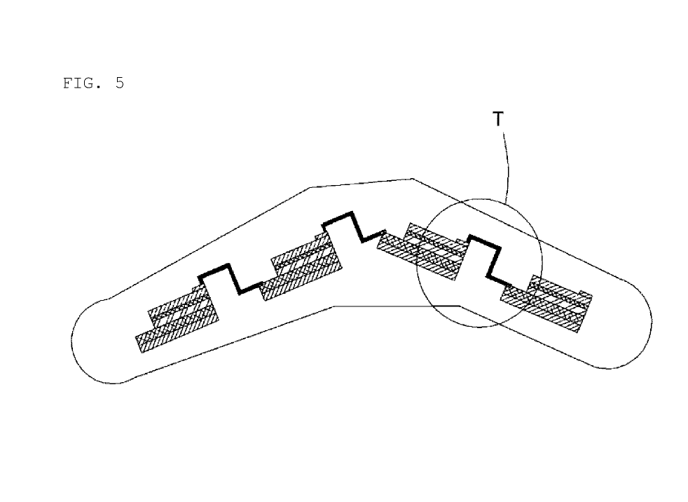

FIG. 1 is a front view illustrating that solar cells are connected through an interconnection ribbon in the related art. FIG. 2 is a plan view illustrating that the solar cells are connected through the interconnection ribbon in the related art. FIG. 3 is a plan view illustrating a solar cell module formed by interconnection ribbons in the related art. FIG. 4 is a front view illustrating the solar cell module formed by the interconnection ribbons in the related art. FIG. 5 is a view illustrating a problem of the solar cell module formed by the interconnection ribbons in the related art.

Referring to FIG. 1, a unit solar cell may include a substrate 1, a first electrode 2, a light absorption layer 3, a buffer layer 4, a transparent electrode 5, and a second electrode 6. In order to connect one unit solar cell to the other solar cell, an interconnection ribbon 7 is used.

Referring to FIG. 1 and FIG. 2, the solar cells are connected through the interconnection ribbon 7, and a solar cell module is formed by performing lamination as illustrated in FIG. 3 and FIG. 4.

Referring to FIG. 5, when the solar cell module is bent, tension is applied to the interconnection ribbon in the related art, and thus there is a problem that a connection portion T may be disconnected.

Hereinafter, at least some embodiments of the invention will be described in detail with reference to the drawings.

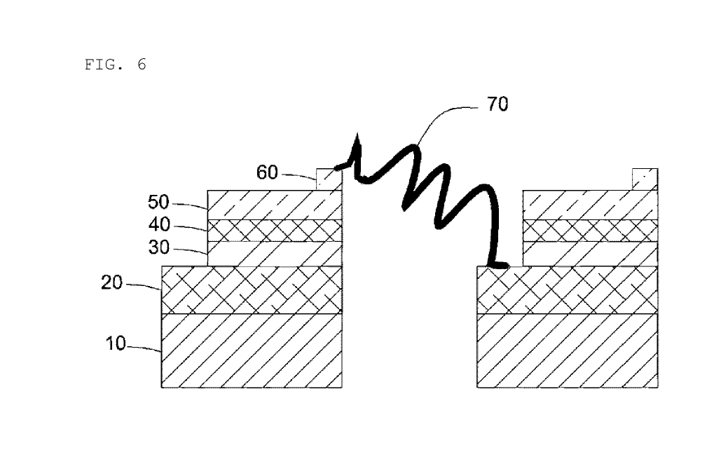

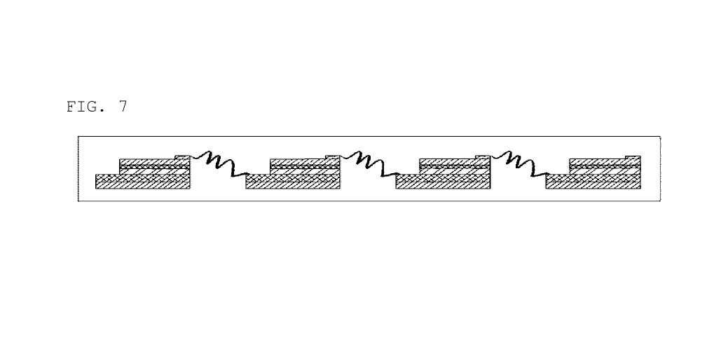

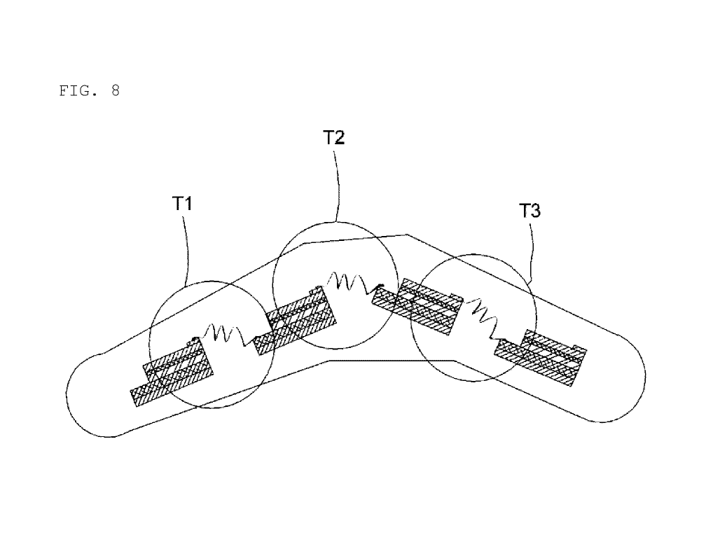

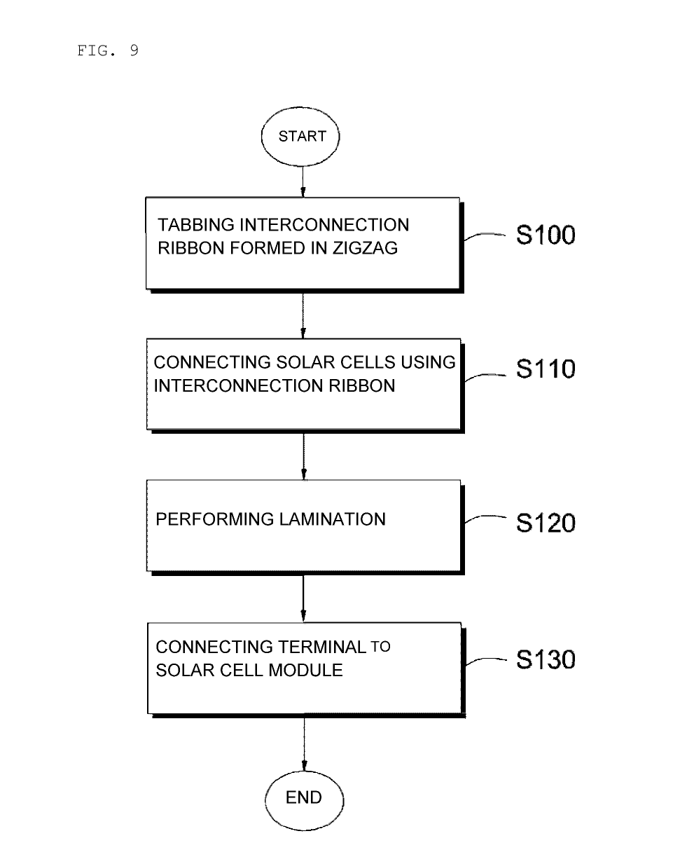

FIG. 6 is a front view illustrating that solar cells are connected through an interconnection ribbon according to some embodiments of the invention. FIG. 7 is a front view illustrating a solar cell module according to some embodiments of the invention. FIG. 8 is a view for explaining an effect of the solar cell module according to some embodiments of the invention. FIG. 9 is a flowchart illustrating a method for manufacturing the solar cell module according to some embodiments of the invention.

Referring to FIG. 6, it can be seen that an interconnection ribbon 70 according to some embodiments of the invention is formed in zigzag to reduce tension generated according to bending of a solar cell module.

As described above, a solar cell that is a configuration of the solar cell module may include a substrate 10, a first electrode 20, a light absorption layer 30, a buffer layer 40, a transparent electrode 50, and a second electrode 60. In this case, the substrate 10 may be a flexible substrate.

Specifically describing a configuration of the solar cell, the first electrode 20 may be any one of nickel, copper, and molybdenum.

In addition, the light absorption layer 30 may be any one selected from the CIS/CIGS-based group including Cu—In—Se, Cu—In—S, Cu—Ga—S, Cu—Ga—Se, Cu—In—Ga—Se, Cu—In—Ga—Se(S,Se), Cu—In-Ai-Ga—(S,Se), and Cu—In—Al—Ga—Se—S.

In addition, the buffer layer 40 may include at least any one of CdS, CdZnS, ZnS, Zn(S,O), Zn(OH,S), ZnSe, ZnInS, ZnInSe, ZnMgO, Zn(Se,OH), ZnSnO, ZnO, InSe, InOH, In(OH,S), In(OOH,S), and In(S,O).

In addition, the second electrode 60 may include at least any one of zinc oxide, gallium oxide, aluminum oxide, indium oxide, lead oxide, copper oxide, titanium oxide, tin oxide, iron oxide, tin dioxide, and indium tin oxide.

In addition, the interconnection ribbon 70 may be formed of a copper (Cu) electrode coated with alloy including lead (Pb), and preferably, the alloy including the lead (Pb) may be tin-lead (Sn—Pb) alloy or tin-lead-silver (Sn—Pb—Ag) alloy. However, the above description merely means preferable examples, and is not limited to the examples described above.

Referring to FIG. 7, a solar cell module 100 according to some embodiments of the invention is illustrated. Specifically, as described above, the solar cell module in which the solar cells are connected through the interconnection ribbon formed in zigzag to reduce tension generated according to bending of the solar cell module is a solar cell module which is generated as a result of sequentially stacking tempered glass, an EVA sheet, the connected solar cell, an EVA sheet, and a back sheet, and then performing lamination.

Generally, a solar power (PV photovoltaic) system includes a solar cell, a solar cell module, a solar cell panel, a solar cell array, a power conversion system (PCS), a power storage device, and the like. The solar cell module plays a role of receiving light and converting the light into electricity. Generally, in the solar cell module, a plurality of solar cells are disposed, and the solar cell is connected through an interconnection ribbon and include glass, a filler (EVA), and a back sheet.

The glass protects the solar cell from external impact or the like, and may be tempered glass. The glass may have waterproof, insulating, and ultraviolet blocking functions. The glass may be manufactured in various shapes such as rectangular and circular according to installation environment and design.

In addition, a protective film may be formed under a lower face of the glass. The protective film may be an ultraviolet blocking film or the like, and blocks ultraviolet light or the like transferred to the solar cell through the glass to help extending the life of the solar cell. However, if the glass itself has a sufficient ultraviolet blocking function, the protective film may not be provided.

The tempered glass is glass obtained by heating a formed plate glass to 500 to 600° C. close to a softening temperature, and rapidly cooling it by compressed cooling air to compressively deform a glass surface portion and to tensile-deform the inside to be tempered. The tempered glass is excellent in bending strength, impact resistance, and heat resistance as compared with normal glass, protects the solar cell from external force, and allows sun light to effectively pass.

The filler (EVA) is an essential material for keeping the life of the solar cell module long, is positioned on front and rear faces of the solar cell, and plays a role of a cushion for preventing the solar cell from being broken and a role of adhering and sealing the front glass and the rear back sheet.

The back sheet 105 may be made of fluorine resin based TPT (TEDLAR/PET/TEDLAR) (TEDLAR from DuPont, Wilmington, Del.) and PET (poly-ethylene terephtalate) type synthetic resin, and has waterproof, insulating, and ultraviolet blocking functions.

Specifically describing an effect according to some embodiments of the invention with reference to FIG. 8, when the solar cell module according to some embodiments of the invention is bent, there is an effect of reducing tension since the interconnection ribbon for connecting the solar cells is formed in zigzag.

For example, a length of the interconnection ribbon may be inversely proportional to a minimum radius of curvature that is a radius in a state where the solar cell module is bent to the maximum.

In other words, as the bending extent gets stronger, the length of the interconnection ribbon may be further extended.

In addition, a length of the first interconnection ribbon connected between the first solar cell and the second solar cell of the plurality of solar cells may be different from a length of the second interconnection ribbon connected between the second solar cell and the third solar cell of the plurality of solar cells.

Specifically, referring to FIG. 8, tension T1 generated on the first interconnection ribbon connected between the first solar cell and the second solar cell is larger than tension T2 generated on the second interconnection ribbon connected between the second solar cell and the third solar cell and, in this case, the first interconnection ribbon may be formed to be longer.

In other words, since tensions generated on the plurality of interconnection ribbons are different from each other, the plurality of interconnection ribbons may be formed to be different in length from each other by reflecting the difference.

Referring to FIG. 9, a method for manufacturing a solar cell module according to some embodiments of the invention is a method for manufacturing a solar cell module in which a plurality of solar cells are connected in series or in parallel through interconnection ribbons.

A step (S100) of tabbing interconnection ribbons which are formed in zigzag to reduce tension generated according to bending of the solar cell module, to bus bars formed in the solar cells is performed.

Then, a step (5110) of connecting the solar cells by interconnecting the solar cells using the interconnection ribbons attached to the bus bars is performed, and a step (S120) of sequentially stacking tempered glass, an EVA sheet, the connected solar cell, an EVA sheet, and a back sheet, and then performing lamination is performed.

A step (S130) of connecting a terminal to the solar cell module is performed, thereby completing the method.

The same and overlapped technical description as the solar cell module according to some embodiments of the invention is omitted.

As described above, according to the solar cell module, the manufacturing method, the interconnection ribbon, and the solar power system according to some embodiments of the invention, the interconnection ribbon for connecting the plurality of solar cells is formed in zigzag to reduce tension generated according to bending of the solar cell module, thereby preventing the interconnection ribbon from being disconnected.

The invention described above is not limited to the configuration and the method of the embodiments described above, and all or some of the embodiments may be combined and configured to variously modify the embodiments.

According to some embodiments of the invention, there is an effect of reducing tension generated according to bending of a solar cell module by forming, in zigzag, interconnection ribbons for connecting a plurality of solar cells.

While the present invention has been described with respect to the specific embodiments, it will be apparent to those skilled in the art that various changes and modifications may be made without departing from the spirit and scope of some embodiments of the invention as defined in the following claims.

### REFERENCE SIGNS

100: SOLAR CELL MODULE
10: SUBSTRATE
20: FIRST ELECTRODE
30: LIGHT ABSORPTION LAYER
40: BUFFER LAYER
50: TRANSPARENT ELECTRODE
60: SECOND ELECTRODE
70: INTERCONNECTION RIBBON

What is claimed is:

1. A solar cell module comprising a plurality of solar cells which are connected in series or in parallel through interconnection ribbons, wherein the interconnection ribbons comprise a zigzag shape to reduce tension generated according to bending of the solar cell module.

2. The solar cell module according to claim 1, wherein a length of the interconnection ribbon is inversely proportional to a minimum radius of curvature that is a radius in a state where the solar cell module is bent to the maximum.

3. The solar cell module according to claim 1, wherein a length of a first interconnection ribbon connected between a first solar cell and a second solar cell of the plurality of solar cells is different from a length of a second interconnection ribbon connected between the second solar cell and a third solar cell of the plurality of solar cells.

4. The solar cell module according to claim 1, wherein the interconnection ribbons are formed of copper (Cu) electrodes coated with an alloy that includes lead (Pb).

5. The solar cell module according to claim 4, wherein the alloy including lead (Pb) is a tin-lead (Sn—Pb) alloy or tin-lead-silver (Sn—Pb—Ag) alloy.

6. The solar cell module according to claim 1, wherein the plurality of solar cells comprise flexible substrates.

7. A method for manufacturing a solar cell module including a plurality of solar cells connected in series or in parallel through interconnection ribbons, the method comprising:
attaching interconnection ribbons which comprise a zigzag shape to reduce tension generated according to bending of the solar cell module, to bus bars formed in the solar cells;
connecting the solar cells by interconnecting the solar cells using the interconnection ribbons attached to the bus bars;
sequentially stacking tempered glass, a first EVA sheet, the connected solar cells, a second EVA sheet, and a back sheet, and then performing lamination; and
connecting a terminal to the solar cell module.

8. The method for manufacturing a solar cell module according to claim 7, wherein a length of the interconnection ribbon is inversely proportional to a minimum radius of curvature that is a radius in a state where the solar cell module is bent to the maximum.

9. The method for manufacturing a solar cell module according to claim 7, wherein a length of a first interconnection ribbon connected between a first solar cell and a second solar cell of the plurality of solar cells is different from a length of the second interconnection ribbon connected between the second solar cell and a third solar cell of the plurality of solar cells.

10. The method for manufacturing a solar cell module according to claim 7, wherein the interconnection ribbons are formed of copper (Cu) electrodes coated with an alloy that includes lead (Pb).

11. The solar cell module according to claim 10, wherein the alloy including lead (Pb) is tin-lead (Sn—Pb) alloy or tin-lead-silver (Sn—Pb—Ag) alloy.

12. A solar power system comprising the solar cell module according to claim 1.

13. An interconnection ribbon which connects a plurality of solar cells in series or in parallel, wherein the interconnection ribbon comprises a zigzag shape to reduce tension generated according to bending of a solar cell module formed by connecting a plurality of solar cell.

14. The interconnection ribbon according to claim 13, wherein a length of the interconnection ribbon is inversely proportional to a minimum radius of curvature that is a radius in a state where the solar cell module is bent to the maximum.
